(19) United States
(12) Patent Application Publication
(10) Pub. No.: US 2025/0102632 A1
(43) Pub. Date: Mar. 27, 2025

(54) MINIATURIZED LIDAR MODULE

(71) Applicant: Lumentum Operations LLC, San Jose, CA (US)

(72) Inventors: Chong Yang QIN, Dongguan City (CN); Xianwen Feng, Dongguan City (CN); Zhiren Wang, Dongguan City (CN)

(21) Appl. No.: 18/798,156

(22) Filed: Aug. 8, 2024

(30) Foreign Application Priority Data
Sep. 23, 2023 (CN) 202311234038.0

(51) Int. Cl. G01S 7/481; H05K 1/02; H05K 1/14

(52) U.S. Cl. CPC G01S 7/4813; H05K 1/0212; H05K 1/028; H05K 1/147; H05K 2201/041

(57) ABSTRACT

The present invention relates to the field of LIDAR technology, and in particular to a miniaturized LIDAR module. A miniaturized LIDAR module comprises a mounting housing, a circuit board arranged on the mounting housing, and a laser transceiver assembly arranged on the mounting housing and electrically connected to the circuit board. The mounting housing comprises a circuit board mounting portion arranged to carry the circuit board. The circuit board comprises at least one rigid circuit board and at least one flexible electrical connector electrically connected to the rigid circuit board. The circuit board is a bent structure with an opening at one end and stuck on the circuit board mounting portion. The miniaturized LIDAR module according to the present invention is compact in structure, excellent in structural stability, simple in the assembling process and small in size, and exhibits an excellent compatibility when applied to the whole system.

### FIELD

The present invention relates to the field of LIDAR technology, and in particular to a miniaturized LIDAR module.

### BACKGROUND

LIDAR is a radar system which emits a laser beam to detect a feature quantity such as a position and velocity of a target. Specifically, the LIDAR may obtain relevant parameters such as the distance and velocity of the target by emitting a laser beam (a single ray or multiple rays) to the target, then comparing a reflected signal with the emitted signal, and analyzing a Time of Flight (TOF) or a frequency difference (Doppler frequency shift) for the signals.

With the constant development of intelligent driving and intelligent robot technology, the LIDAR is a core sensor thereof, so there are higher and higher requirements for the production cost, volume and power consumption of the LIDAR in the industry. In order to adapt the LIDAR to various scenarios, particularly when the requirements for the size of the LIDAR becomes higher and higher, a small-sized LIDAR module is desired.

### SUMMARY

An object of the present invention to overcome the above drawbacks in the prior art. The present invention provides a miniaturized LIDAR module with a simple assembly process and good compatibility.

In order to solve the above technical problems, the present invention employs the following technical solutions.

A miniaturized LIDAR module includes a mounting housing, a circuit board arranged on the mounting housing, and a laser transceiver assembly arranged on the mounting housing and electrically connected to the circuit board. The mounting housing includes a circuit board mounting portion for carrying the circuit board.

The circuit board includes at least one rigid circuit board and at least one flexible electrical connector electrically connected to the rigid circuit board; and the circuit board is a bent structure with an opening at one end and stuck on the circuit board mounting portion.

On the one hand, such a circuit board has a compact structure, facilitates the reduction of the size thereof so that the LIDAR module can be adapted to various scenarios with good compatibility. On the other hand, as compared with the alignment assembly required when pins are employed to achieve electrical connection in the prior art, the present invention simplifies the assembling process and facilitates reducing the production cost. Meanwhile, the present invention can also solve the problem of poor reliability such as poor contact during long-term use. In addition, the structure of the LIDAR module exhibits excellent stability and ensures that the LIDAR module can operate normally in a long term.

Furthermore, the circuit board includes a first PCB board arranged on an upper surface of the circuit board mounting portion, a second PCB board arranged on a lower surface of the circuit board mounting portion and opposite to the first PCB board, and at least one first flexible circuit board arranged to connect the first PCB board with the second PCB board. The first flexible circuit board may be bent so that the first PCB board and the second PCB board are arranged opposite to each other, thereby saving the space occupied by the circuit board and meanwhile facilitating the arrangement of other components. In addition, the first PCB board is arranged on the upper surface of the circuit board mounting portion and the second PCB board is arranged on the lower surface of the circuit board mounting portion, which is also advantageous to reduce electromagnetic interference therebetween.

Preferably, the first PCB board, the second PCB board and the first flexible circuit board are in an integral form. In production, supply of an integral material of the circuit board can be achieved.

Preferably, a cross-sectional shape of the circuit board matches that of the circuit board mounting portion, and the first flexible circuit board is closely contacted with an end of the circuit board mounting portion away from the opening, thereby saving the space occupied by the circuit board, facilitating the arrangement of other components, facilitating an operator to fit the circuit board on the circuit board mounting portion and facilitating simplifying the assembling process.

Furthermore, a first accommodating cavity arranged to carry the laser transceiver assembly is provided at the top of the mounting housing; a second accommodating cavity is provided on a bottom of the mounting housing, a through hole arranged to communicate the first accommodating cavity with the second accommodating cavity is disposed on the second accommodating cavity; a temperature controller is disposed on a bottom of the laser transceiver assembly; and the temperature controller is arranged to be electrically connected to the circuit board.

Preferably, a base plate is detachably arranged on a bottom of the mounting housing; an upper housing is detachably arranged on a top of the mounting housing; and the base plate, the mounting housing and the upper housing are matched with each other to form a package structure to accommodate the temperature controller, the circuit board and the laser transceiver assembly.

Preferably, the base plate is provided with a placement seat, and the placement seat is arranged in the second accommodating cavity and located below the through hole; and the temperature controller is arranged on the placement seat and connected to the laser transceiver assembly through the through hole.

Preferably, the temperature controller includes a semiconductor cooler arranged on the placement seat and having a cold end contacted with and connected to the bottom of the laser transceiver assembly, and a connector having one end connected to the semiconductor cooler and the other end electrically connected to the circuit board. The semiconductor cooler can adjust the temperature of the laser transceiver assembly to ensure the normal operation of the LIDAR module.

Preferably, the connector is a second flexible circuit board; the connector includes a first connecting portion connected to the semiconductor cooler and arranged on a bottom of the circuit board mounting portion, a third connecting portion arranged on the bottom of the circuit board, and a second connecting portion arranged to connect the first connecting portion with the third connecting portion.

Preferably, the first connecting portion, the second connecting portion and the third connecting portion form a connector having a zigzag shape; and the first connecting portion, the second connecting portion and the third connecting portion are in an integral form.

The advantageous effects of the present invention compared with the prior art are as follows.
1. On the one hand, in the miniaturized LIDAR module according to the present invention, the circuit board includes the first PCB board, the second PCB board and the first flexible circuit board, the first flexible circuit board is bendable so that the first PCB board and second PCB board are disposed opposite to each other, thereby saving the space occupied by the circuit board, and meanwhile facilitating the arrangement of other components. The compact structure of the LIDAR module facilitates the reduction of the size thereof so that the LIDAR module can be adapted to various scenarios with good compatibility. On the other hand, the first PCB board is disposed on the upper surface of the circuit board mounting portion and the second PCB board is disposed on the lower surface of the circuit board mounting portion, which is also advantageous to reduce electromagnetic interference therebetween.
2. The first PCB board, the second PCB board and the first flexible circuit board are in an integral form. In production, supply of an integral material of the circuit board can be achieved. Furthermore, as compared with alignment assembling in the prior art when two PCBs need to achieve electrical connection via pins, the assembling process in the present invention simplifies the assembling process and facilitates reducing the production cost. Meanwhile, the assembling process can also solve the problem of poor reliability such as poor contact during long-term use. The structure of the LIDAR module exhibits excellent stability and ensures that the LIDAR module can operate normally in a long term.
3. The temperature controller includes a semiconductor cooler and a connector, one end of the connector is connected to the semiconductor cooler, and the other end of the connector is electrically connected to the circuit board. This solves the problem of electromagnetic interference caused by two separate positive and negative lead wires when the semiconductor cooler uses two separate positive and negative lead wires to electrically connect with the circuit board in the prior art.

### BRIEF DESCRIPTION OF THE DRAWINGS

FIG. 1 is an overall structural schematic diagram of a miniaturized LIDAR module according to the present invention;

FIG. 2 is an perspective structural schematic diagram of a miniaturized LIDAR module according to the present invention;

FIG. 3 is a cross-sectional view of a miniaturized LIDAR module according to the present invention;

FIG. 4 is a structural schematic diagram of a mounting housing in a miniaturized LIDAR module according to the present invention;

FIG. 5 is a structural schematic diagram of a mounting housing in a miniaturized LIDAR module according to the present invention as viewed from another perspective;

FIG. 6 is a structural schematic diagram of a temperature controller in a miniaturized LIDAR module according to the present invention; and

FIG. 7 is a structural schematic diagram of a circuit board in a miniaturized LIDAR module according to the present invention.

Listing of Reference Numerals

1—a base plate; 11—Placement seat; 12—First screw hole; 2—Mounting housing; 21—First accommodating cavity; 22—Second accommodating cavity; 23—Through hole; 24—Circuit board mounting portion; 25—Notch; 26—Second screw hole; 27—Third screw hole; 3—Upper housing; 31—Upper cover plate; 311—Fourth screw hole; 32—Side plate; 4—Temperature controller; 41—Semiconductor cooler; 42—Connector; 421—First connecting portion; 422—Second connecting portion; 423—Third connecting portion; 5—Circuit board; 51—First PCB board; 52—Second PCB board; 53—First flexible circuit board; 6—Laser transceiver assembly; 7—First fastener; 8—Second fastener.

### DETAILED DESCRIPTION

To make the objects, technical solutions and advantages of embodiments of the present invention more apparent, technical solutions in embodiments of the present invention will be clearly and completely described with reference to the figures in embodiments in the present invention. Obviously, the embodiments described here are part of rather than all embodiments of the present disclosure. Based on embodiments in the present invention, all other embodiments obtained by those skilled in the art without making any inventive efforts all fall within the scope of protection of the present invention.

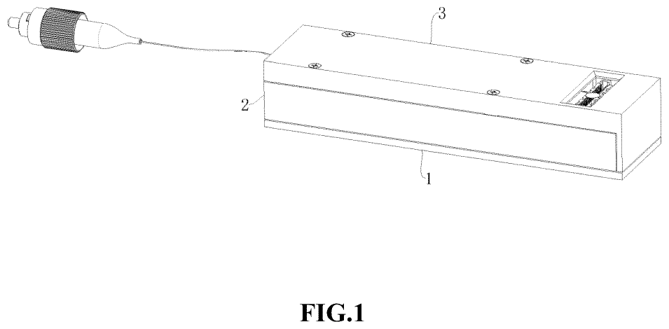

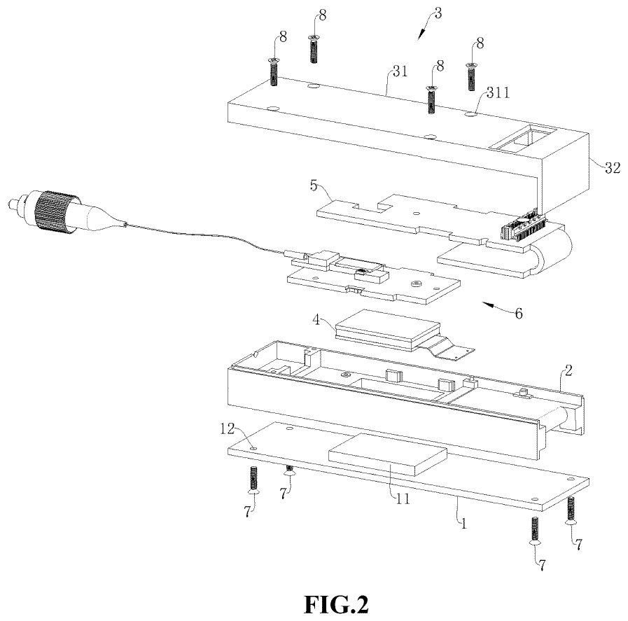

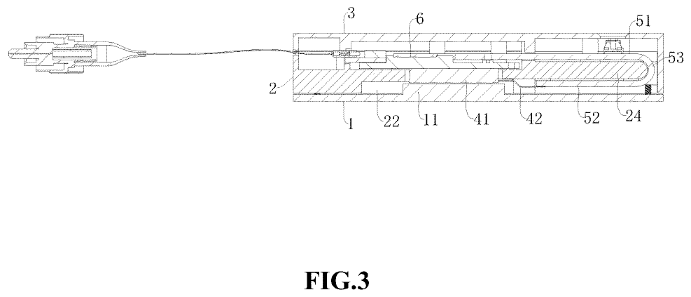

Referring to FIG. 1 through FIG. 3, there is provided a miniaturized LIDAR module according to one embodiment of the present invention. The miniaturized LIDAR module includes a base plate 1, a mounting housing 2, an upper housing 3, a temperature controller 4, a circuit board 5, a laser transceiver assembly 6, a plurality of first fasteners 7 and a plurality of second fasteners 8. The mounting housing 2 is detachably arranged on the top of the base plate 1, and the upper housing 3 is detachably arranged on the top of the mounting housing 2. The temperature controller 4, the circuit board 5 and the laser transceiver assembly 6 are accommodated in a package structure formed by the base plate 1, the mounting housing 2 and the upper housing 3 by matching with each other. Specifically, the circuit board 5 is arranged on the mounting housing 2, and the laser transceiver assembly 6 is arranged on the mounting housing 2 and electrically connected to the circuit board 5 and configured to emit a laser and receive a detection signal. The temperature controller 4 is arranged on the bottom of the laser transceiver assembly 6 and electrically connected to the circuit board 5 and configured to adjust the temperature of the laser transceiver assembly 6 to ensure the normal operation of the IDAR module.

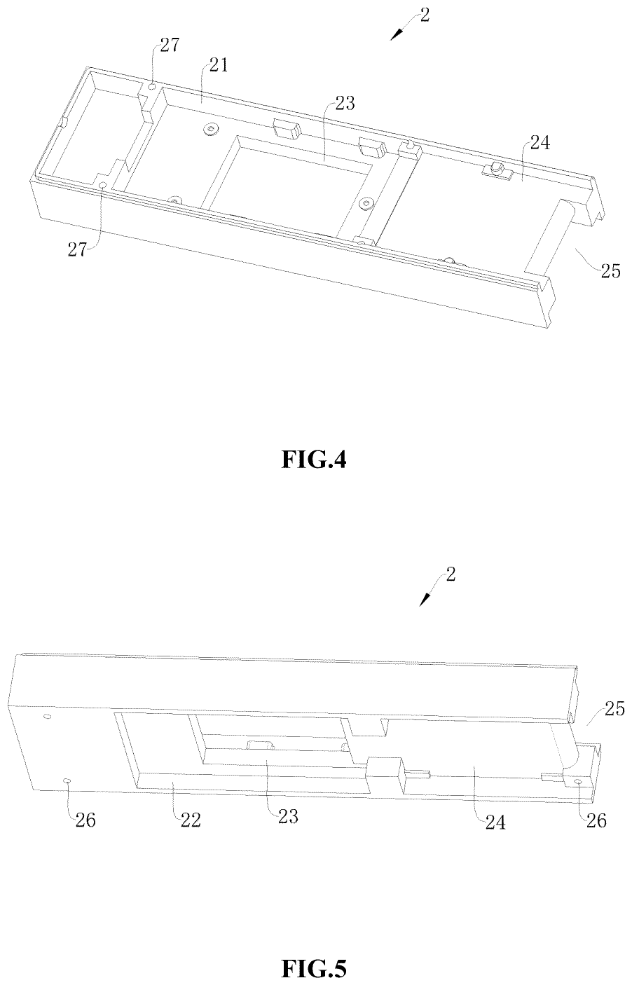

Referring to FIG. 4 and FIG. 5 together, the mounting housing 2 has a housing structure with a notch 25 at one end. Specifically, a first accommodating cavity 21 arranged to carry the laser transceiver assembly 6 is provided at the top of the mounting housing 2, and a second accommodating cavity 22 arranged opposite to the first accommodating cavity 21 is provided on the bottom of the mounting housing 2. In addition, a through hole 23 is disposed on the second accommodating cavity 22, and the through hole 23 is arranged to communicate the first accommodating cavity 21 with the second accommodating cavity 22. The mounting housing 2 includes a circuit board mounting portion 24 which is located at one end of the mounting housing 2 adjacent the notch 25 and arranged to carry the circuit board 5.

The circuit board 5 includes at least one rigid circuit board and at least one flexible electrical connector, wherein the flexible electrical connector is electrically connected to the rigid circuit board. The circuit board 5 has a bent structure with an opening at one end and is stuck on the circuit board mounting portion 24. Referring to FIG. 7 also, in the present embodiment, the circuit board 5 includes a first PCB board 51, a second PCB board 52, and a first flexible circuit board 53. The first PCB board 51 is disposed on an upper surface of the circuit board mounting portion 24. The second PCB board 52 is disposed on a lower surface of the circuit board mounting portion 24, and opposite to the first PCB board 51. The first flexible circuit board 53 is used to connect the first PCB board 51 with the second PCB board 52. Preferably, the upper surface of the circuit board mounting portion 24 is flush with the upper surface of the laser transceiver assembly 6 housed in the first accommodating cavity 21. The first PCB board 51 is further arranged on the upper surface of the laser transceiver assembly 6 and electrically connected to the laser transceiver assembly 6. The LIDAR module has a compact structure, in the present embodiment, the laser transceiver assembly 6 achieves electrical connection with the first PCB board 51 by gold wire bonding.

Specifically, the first PCB board 51 and the second PCB board 52 are respectively disposed on the upper and lower surfaces of the circuit board mounting portion 24, which can not only save the space occupied by the circuit board 5 in the LIDAR module, but also facilitate reducing electromagnetic interference therebetween, thereby facilitating improving the performance and accuracy of the LIDAR module. In addition, the first PCB board 51, the second PCB board 52 and the first flexible circuit board 53 are in an integral form, and during production, supply of an integral material of the circuit board 5 can be achieved. A cross-sectional shape of the circuit board 5 matches that of the circuit board mounting portion 24; in the present embodiment, the first flexible circuit board 53 is bent into an arc-shaped structure, an end portion of the circuit board mounting portion 24 away from the opening thereof is also in an arc-shaped structure, and the first flexible circuit board 53 can be closely fitted with the end portion of the circuit board mounting portion 24 away from the opening thereof, thereby further saving the space occupied by the circuit board 5, facilitating the arrangement of other components in the LIDAR module, and thereby facilitating the reduction of the size of the LIDAR module.

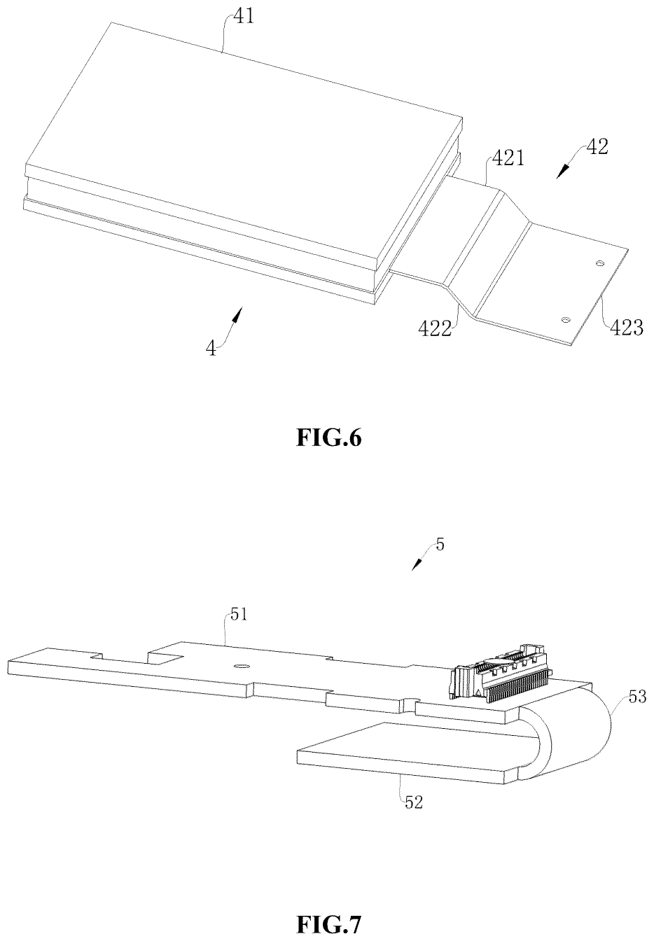

The base plate 1 is provided with a placement seat 11, wherein the placement seat 11 is disposed in the second accommodating cavity 22 and located below the through hole 23. The temperature controller 4 is arranged on the placement seat 11 and connected to the laser transceiver assembly 6 through the through hole 23. Referring to FIG. 6, the temperature controller 4 includes a semiconductor cooler 41 and a connector 42. The semiconductor cooler 41 is arranged on the placement seat 11, and a cold end of the semiconductor cooler 41 is contacted with and connected to the bottom of the laser transceiver assembly 6 and configured to adjust the temperature of the laser transceiver assembly 6. One end of the connector 42 is connected to the semiconductor cooler 41, and the other end of the connector 42 is electrically connected to the circuit board 5.

The connector 42 is a second flexible circuit board, and the connector 42 includes a first connecting portion 421, a second connecting portion 422 and a third connecting portion 423. The first connecting portion 421 is connected to the semiconductor cooler 41, and the first connecting portion 421 is arranged at the bottom of the circuit board mounting portion 24. The third connecting portion 423 is arranged on the bottom of the circuit board 5 and electrically connected to the circuit board 5. The second connecting portion 422 connects the first connecting portion 421 with the third connecting portion 423. The first connecting portion 421, the second connecting portion 422 and the third connecting portion 423 are in an integral form. The first connecting portion 421, the second connecting portion 422 and the third connecting portion 423 form the connector 42 having a zigzag shape.

The base plate 1, the mounting housing 2 and the upper housing 3 are all metal members. The base plate 1 is used for dissipating heat, and the upper housing 3 serves to protect parts in the LIDAR module. The base plate 1 is detachably connected to the mounting housing 2, and the mounting housing 2 and the upper housing 3 are also detachably connected. Specifically, a plurality of first screw holes 12 are provided on the base plate 1; a plurality of second screw holes 26 are provided on the bottom of the mounting housing 2, and the second screw holes 26 correspond one-to-one with the first screw holes 12. A first fastener 7 is employed to pass through the first screw hole 12 and the second screw hole 26 and fasten the mounting housing 2 to the base plate 1. In the present embodiment, the first fastener 7 is a bolt. In other embodiments, the first fastener 7 may also be provided as a screw. Therefore, the form of the first fastener 7 is not limited herein.

The upper housing 3 includes an upper cover plate 31 and a side plate 32. One end of the side plate 32 is vertically arranged at one end of the upper cover plate 31 close to the notch 25, and the other end of the side plate 32 abuts against the top of the base plate 1. The upper cover plate 31 and the side plate 32 are in an integral form. The base plate 1, the mounting housing 2 and the upper housing 3 are matched with each other to form a package structure. The upper cover plate 31 is detachably connected to the mounting housing 2, a plurality of third screw holes 27 are disposed on the top of the mounting housing 2, a plurality of fourth screw holes 311 are disposed on the upper cover plate 31, and the fourth screw holes 311 correspond one-to-one with the third screw holes 27. A second fastener 8 is employed to pass through the fourth screw hole 311 and the third screw hole 27 and fastens the upper housing 3 with the mounting housing 2. In the present embodiment, the second fastener 8 is a bolt. In other embodiments, the second fastener 8 may also be provided as a screw. Therefore, the form of the second fastener 8 is not limited herein.

Upon assembling, an operator can complete the installation of the circuit board 5 by fitting the circuit board 5 on the circuit board mounting portion 24. As compared with alignment assembling in the prior art when two PCBs need to achieve electrical connection via pins, the assembling process in the present invention is simple, facilitates improving the production efficiency and reducing the production cost. Meanwhile, the assembling process can also solve the problem of poor reliability such as poor contact during long-term use. In addition, the compact structure of the LIDAR module facilitates the reduction of the size thereof so that the LIDAR module can be adapted to various scenarios with good compatibility.

The above embodiments are preferred embodiments of the present invention, but embodiments of the present invention are not limited by the above embodiments. Any other variations, modifications, substitutes, combinations and simplifications made without departing from the spirit, essence and principles of the present inventions all should be equivalent replacements and all fall within the scope of protection of the present invention.

I/we claim:

1. A miniaturized LIDAR module, comprising: a mounting housing (2), a circuit board (5) arranged on the mounting housing (2), and a laser transceiver assembly (6) arranged on the mounting housing (2) and electrically connected to the circuit board (5), the mounting housing (2) comprises a circuit board mounting portion (24) arranged to support the circuit board (5);
the circuit board (5) comprises at least one rigid circuit board and at least one flexible electrical connector electrically connected to the rigid circuit board; the circuit board (5) is a bent structure with an opening at one end and stuck on the circuit board mounting portion (24).

2. The miniaturized LIDAR module according to claim 1, wherein the circuit board (5) comprises a first PCB board (51) arranged on an upper surface of the circuit board mounting portion (24), a second PCB board (52) arranged on a lower surface of the circuit board mounting portion (24) and opposite to the first PCB board (51), and at least one first flexible circuit board (53) for connecting the first PCB board (51) with the second PCB board (52).

3. The miniaturized LIDAR module according to claim 2, wherein the first PCB board (51), the second PCB board (52) and the first flexible circuit board (53) are in an integral form.

4. The miniaturized LIDAR module according to claim 2, wherein a cross-sectional shape of the circuit board (5) is matched with a cross-sectional shape of the circuit board mounting portion (24); the first flexible circuit board (53) is in close contact with an end of the circuit board mounting portion (24) away from the opening.

5. The miniaturized LIDAR module according to claim 1, wherein a top of the mounting housing (2) is provided with a first accommodating cavity (21) for supporting the laser transceiver assembly (6); a bottom of the mounting housing (2) is provided with a second accommodating cavity (22), which is provided thereon with a through hole (23) communicating the first accommodating cavity (21) with the second accommodating cavity (22); a bottom of the laser transceiver assembly (6) is provided with a temperature controller (4) electrically connected to the circuit board (5).

6. The miniaturized LIDAR module according to claim 5, wherein a base plate (1) is detachably arranged on a bottom of the mounting housing (2); an upper housing (3) is detachably arranged on a top of the mounting housing (2); and the base plate (1), the mounting housing (2) and the upper housing (3) are matched with each other to form a package structure to accommodate the temperature controller (4), the circuit board (5) and the laser transceiver assembly (6).

7. The miniaturized LIDAR module according to claim 6, wherein the base plate (1) is provided with a placement seat (11), and the placement seat (11) is arranged in the second accommodating cavity (22) and located below the through hole (23); and the temperature controller (4) is arranged on the placement seat (11) and connected to the laser transceiver assembly (6) through the through hole (23).

8. The miniaturized LIDAR module according to claim 7, wherein the temperature controller (4) comprises a semiconductor cooler (41) arranged on the placement seat (11) and having a cold end being in contact with and connected to the bottom of the laser transceiver assembly (6), and a connector (42) having one end connected to the semiconductor cooler (41) and the other end electrically connected to the circuit board (5).

9. The miniaturized LIDAR module according to claim 8, wherein the connector (42) is a second flexible circuit board; the connector (42) comprises a first connecting portion (421) connected to the semiconductor cooler (41) and arranged on a bottom of the circuit board mounting portion (24), a third connecting portion (423) arranged on the bottom of the circuit board (5), and a second connecting portion (422) connecting the first connecting portion (421) with the third connecting portion (423).

10. The miniaturized LIDAR module according to claim 9, wherein the first connecting portion (421), the second connecting portion (422) and the third connecting portion (423) form a connector (42) having a zigzag shape; the first connecting portion (421), the second connecting portion (422) and the third connecting portion (423) are in an integral form.
